(19) United States
(12) Patent Application Publication
(10) Pub. No.: US 2009/0050889 A1
(43) Pub. Date: Feb. 26, 2009

(54) Repairable capacitor for liquid crystal display

(75) Inventors: Liang-Neng Chien, Hsin-Chu (TW); Chih-Yuan Lin, Hsin-Chu (TW); Ko-Chin Yang, Hsin-Chu (TW)

Correspondence Address: BACON & THOMAS, PLLC, 625 SLATERS LANE, FOURTH FLOOR, ALEXANDRIA, VA, 22314-1176, US

(73) Assignee: AU Optronics Corp., Hsin-Chu (TW)

(21) Appl. No.: 12/213,725

(22) Filed: Jun. 24, 2008

(30) Foreign Application Priority Data
Aug. 24, 2007 (TW) 096131391

(51) Int. Cl. H01L 27/088

(52) U.S. Cl. 257/59; 257/E27.009

(57) ABSTRACT

A thin film transistor array substrate, which can repair a current-leakage defect of a storage capacitor, is disclosed. The thin film transistor array substrate of the present invention comprises: a substrate, a plurality of data lines, and a plurality of scan lines, wherein the data lines and the scan lines divide the substrate into a plurality of display units, i.e. pixels. Each of these display units comprises: a thin film transistor, a lower electrode of a storage capacitor, a first dielectric layer covering the lower electrode of a storage capacitor, an upper electrode of the storage capacitor formed on the first dielectric layer, a second dielectric layer covering the upper electrode of a storage capacitor and the thin film transistor, a plurality of openings formed in the second dielectric layer, and a pixel electrode formed on the second dielectric layer. Besides, the lower electrode of the storage capacitor is further divided into a first portion and a second portion, wherein the first portion and the second portion are separate, but are electrically connected with each other.

### BACKGROUND OF THE INVENTION

1. Field of the Invention

The present invention relates to a thin film transistor (TFT) array substrate, and more particularly, to a leakage current repairable TFT array substrate.

2. Description of Related Art

As shown in FIGS. 1A, 1B, and 1C, wherein FIG. 1A is a schematic view of a well-known TFT (thin film transistor) array substrate, FIG. 1B shows the display units of above TFT array substrate in FIG. 1A, and FIG. 1C is a cross-sectional view along A-A′ in FIG. 1B.

With reference to FIG. 1A, a TFT array substrate 1 of prior art includes: a substrate 11, a plurality of data lines 12, and a plurality of scan lines 13. Both data lines 12 and scan lines 13 are provided on the substrate 11, wherein the substrate 11 is preferably a glass substrate. Also, these data lines 12 and scan lines 13 substantially perpendicularly cross each other to form a grid pattern but are not electrically connected with each other, and they divide the substrate 11 into a plurality of display units 14, i.e. pixel units.

As a TFT array substrate of prior art shown in FIGS. 1B and 1C, each of the display units 14 comprises: a TFT 141, a lower electrode 142 of a storage capacitor, a first dielectric layer 143, an upper electrode 144 of the storage capacitor, a second dielectric layer 145, two openings 146, 147, and a pixel electrode 148. Wherein the TFT 141 located on the substrate 11 (FIG. 1A) is a bottom-gate type TFT, and has a source 1411, a gate 1412 and a drain 1413. The source 1411 is electrically connected with one of the neighboring data lines 12, and the gate 1412 is electrically connected with one of the neighboring scan lines 13. Moreover, the lower electrode of a storage capacitor 142 is located in the substrate 11, and the first dielectric layer 143 covers the lower electrode of a storage capacitor 142. The upper electrode of the storage capacitor 144 located on the upper side of the lower electrode of a storage capacitor 142 forms on the first dielectric layer 143. The second dielectric layer 145 covers the TFT 141 and the upper electrode of the storage capacitor 144. Besides, two openings 146, 147 are formed in the second dielectric layer 145 respectively to expose the partial drain 1413 of the TFT 141 and the upper electrode of the storage capacitor 144 located on the lower electrode of a storage capacitor 142, and both these two openings 146, 147 are preferably via holes. The pixel electrode 148 is formed on the second dielectric layer 145, and the material of the pixel electrode 148 is a transparent conductive material, preferably indium tin oxide (ITO) or indium zinc oxide (IZO). The pixel electrode 148 electrically connects with the drain 1413 of the TFT 141 and the upper electrode of the storage capacitor 144 through these two openings 146, 147. Accordingly, the display unit 14 comprises a storage capacitor (not shown) inside because of the first dielectric layer 143, which is located between the lower electrode of a storage capacitor 142 and the upper electrode of the storage capacitor 144.

Moreover, as shown in FIGS. 1B and 1C, when display unit 14 displays, the control signal from the TFT 141 reaches the pixel electrode 148 through the two openings 146, 147, and enhances potential changes to vary the status of the liquid crystal. Also, the pixel electrode 148 electrically connects with the upper electrode 144 of the storage capacitor through the two openings 146, 147. Meanwhile, when the TFT array substrate 1 of prior art is “displaying”, the current from the above storage capacitor (not shown) reaches the pixel electrode 148 to provide pixel electrode 148 with enough operating current to keep its potential.

However, when the “leakage current” occurs in the storage capacitor (not shown) in the display units of a traditional TFT array substrate, i.e. when the first dielectric layer 143 located between the upper electrode of the storage capacitor 144 and the lower electrode of a storage capacitor 142 loses its essential insulating capacity, the storage capacitor (not shown) should not able to operate (storage current) normally, thus the actions of the display units 14 could not remain under the control of TFT 141. At this time, no matter what status (on or off) the display unit 14 is in, the pixel electrode 148 will always be in the same driving potential, i.e. the display unit 14 no longer has two different statuses, thus causing a continuous bright point or a continuous dark point, and moreover, decreasing the quality of the LCDs having such traditional TFT array substrate.

Therefore, research of a TFT array substrate having the property of easily repairing the leakage current of the storage capacitor is a present need.

### SUMMARY OF THE INVENTION

A TFT (thin film transistor) array substrate of the present invention comprises: a substrate; a plurality of data lines locating on the substrate; and a plurality of scan lines locating on the substrate, perpendicularly crossing the data lines to form a grid pattern but not electrically connected with the data lines. The data lines and the scan lines divide the substrate into a plurality of display units, and each of these display units comprises: a TFT located on the substrate and having a source, a gate, and a drain, wherein the source is electrically connected with one of the neighboring data lines, and the gate is electrically connected with one of the neighboring scan lines; a lower electrode of a storage capacitor located on the substrate, wherein the lower electrode is further divided into a first portion and a second portion, and the first portion and the second portion are separated but not electrically connected with each other; a first dielectric layer covering the lower electrode of the storage capacitor; an upper electrode of the storage capacitor formed on the first dielectric layer, wherein the upper electrode of the storage capacitor is located on the upper side of the lower electrode of the storage capacitor; a second dielectric layer covering the thin film transistor (TFT) and the upper electrode of the storage capacitor; a plurality of openings formed in the second dielectric layer, so as to expose a partial drain of the thin film transistor (TFT), the upper electrode of the storage capacitor located on the upper side of the first portion of the lower electrode of the storage capacitor, and the upper electrode of the storage capacitor located on the upper side of the second portion of the lower electrode of the storage capacitor; and a pixel electrode formed on the second dielectric layer, wherein the pixel electrode is electrically connected with the drain of the thin film transistor (TFT) and the upper electrode of the storage capacitor through the openings.

A TFT (thin film transistor) array substrate of the present invention comprises: a substrate; a plurality of data lines located on the substrate; and a plurality of scan lines located on the substrate, wherein the data lines and the scan lines perpendicularly cross each other to form a grid pattern but are not electrically connected with each other. These data lines and scan lines divide the substrate into a plurality of display units, and each of these display units comprises: a TFT located on the substrate and having a source, a gate, and a drain, wherein the source is electrically connected with one of the neighboring data lines, and the gate is electrically connected with one of the neighboring scan lines; a plurality of lower electrodes of a storage capacitor located on the substrate, wherein the lower electrodes of the storage capacitor are separated but electrically connected with each other; a first dielectric layer covering the lower electrode of the storage capacitor; a plurality of upper electrodes of the storage capacitor formed on the first dielectric layer, wherein the upper electrode of the storage capacitor is located on the upper side of the lower electrode of the storage capacitor; a second dielectric layer covering the thin film transistor and the upper electrode of a storage capacitor; a plurality of openings formed in the second dielectric layer, so as to expose a partial drain of the thin film transistor (TFT) and the upper electrode of the storage capacitor located on the upper side of the lower electrode of the storage capacitor; and a pixel electrode formed on the second dielectric layer, wherein the pixel electrode is electrically connected with the drain of the thin film transistor (TFT) and the upper electrode of the storage capacitor through these openings.

Accordingly, the lower electrode of the display unit (pixel unit) of the present TFT array substrate is further divided into a first portion and a second portion, or the display unit has more than two lower electrodes of a storage capacitor electrically connected with each other. Therefore, when the “leakage current” occurs in the storage capacitor in the display units of the TFT array substrate of the present invention, it is possible to use a laser to cut-off the two ends of some parts of the storage capacitor (the first storage capacitor or the second storage capacitor) having “leakage current”, that is, the repairing method of the present invention isolates the normal storage capacitor from the storage capacitor having “leakage current”. Consequently, after repair, the other parts of the storage capacitor having no “leakage current” still store the current inside normally, thus the display units having “leakage current” are recovered and are able to display again and able to be controlled by the TFT thereof.

Besides, comparing to the display units (pixel units) of the traditional TFT array substrate, there are only changes on the shape of the lower electrode of a storage capacitor of the TFT array substrate display units (pixel units) of the present invention, and the shape change (e.g. the lower electrode of a storage capacitor further divided into a first portion or a second portion) can be easily obtained from adjusting the pattern of the mask. Thus, the TFT array substrate of the present invention can be fabricated using the traditional method of fabricating the TFT array substrate without increasing manufacturing cost. Consequently, the “leakage current” occurring in display units (pixel units) of the TFT array substrate of the present invention is easily repaired, so as to reduce the number of defects (i.e. bright point or black point) causing by the “leakage current”, and further to improve the displaying quality of the TFT array substrate of the present invention.

The first portion of the lower electrode of a storage capacitor of the display unit of the TFT array substrate of the present invention can have any widths, the width thereof is preferably the same as the second portion of the lower electrode of a storage capacitor has. The display unit of the TFT array substrate of the present invention can have any type of TFTs, and preferably a TFT having a bottom gate structure. The display unit of the TFT array substrate of the present invention can have pixel electrodes made with any material, preferably indium tin oxide, indium zinc oxide, or transparent conductive material. The display unit of the TFT array substrate of the present invention can have any number of openings formed in the second dielectric layer thereof, and the number is preferably between 2 and 6. These plural lower electrodes of the storage capacitor of the display unit of the TFT array substrate of the present invention can have any width, and preferably these lower electrodes of the storage capacitor have the same width.

### BRIEF DESCRIPTION OF THE DRAWINGS

FIG. 1A is a schematic view of a well-known TFT array substrate;

FIG. 1B is a schematic view of display units of a well-known TFT array substrate;

FIG IC is a cross-section view along line A-A′ of FIG. 1B;

FIG. 2A is a schematic view of a TFT array substrate of Example 1 of the present invention.

FIG. 2B shows the display units of a TFT array substrate of Example 1 of the present invention.

FIG. 2C is a cross-section view along line A-A′ of FIG. 2B.

FIG. 3 is a flowchart showing the method of repairing defects of the TFT array substrate of Example 1.

FIG. 4A shows a display unit of a TFT array substrate of the present invention, wherein the display unit has leakage current.

FIG. 4B is a cross-section view along line C-C′ of FIG. 4A.

FIG. 5A shows the display units of a TFT array substrate of Example 2 of the present invention.

FIG. 5B is a cross-section view along line D-D′ of FIG SA.

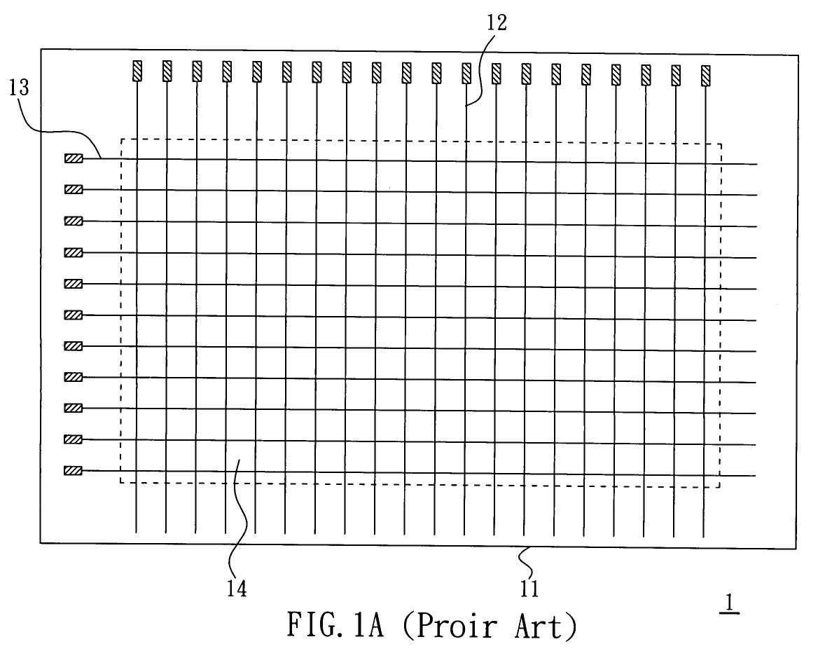

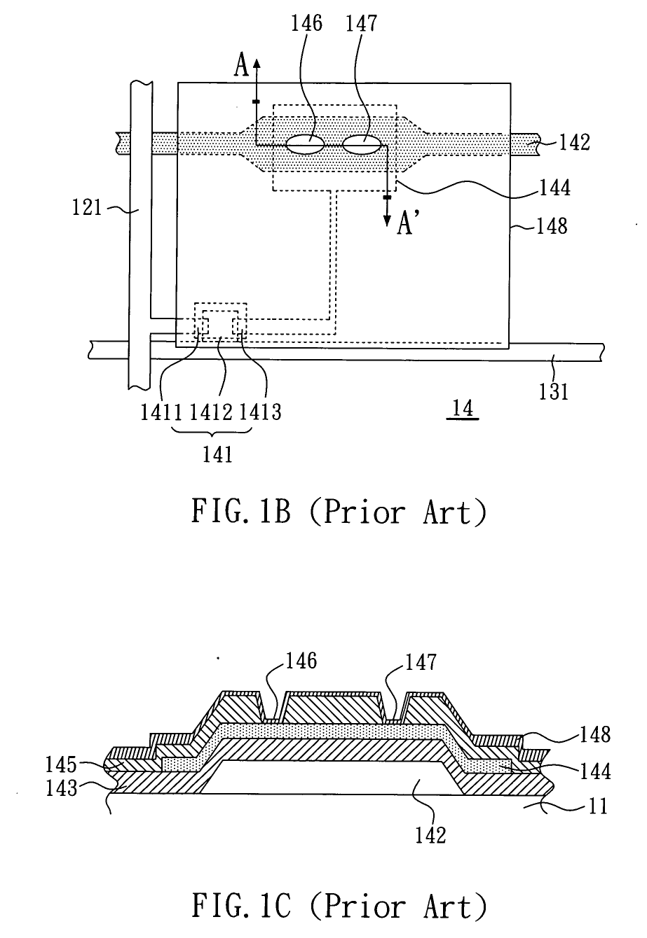

### DETAILED DESCRIPTION OF THE PREFERRED EMBODIMENTS

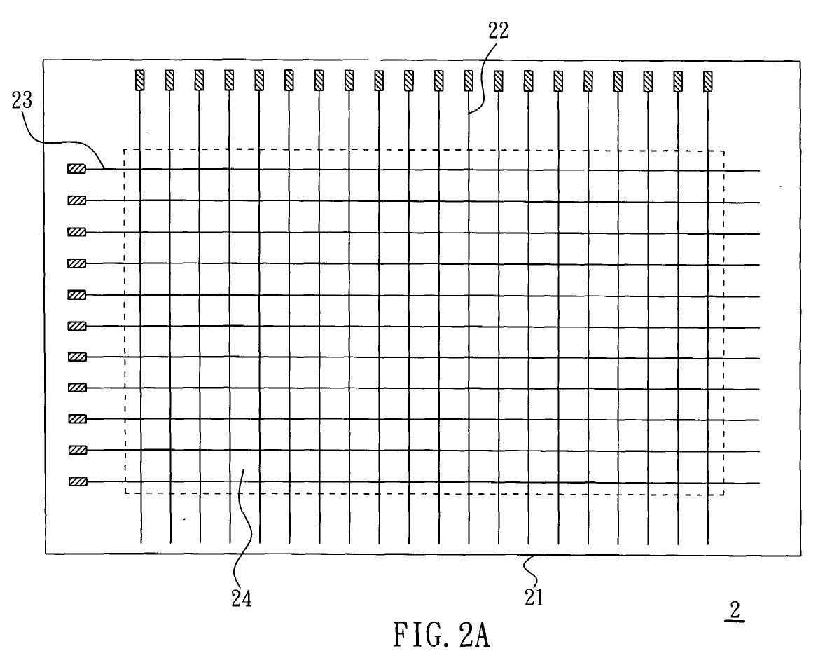

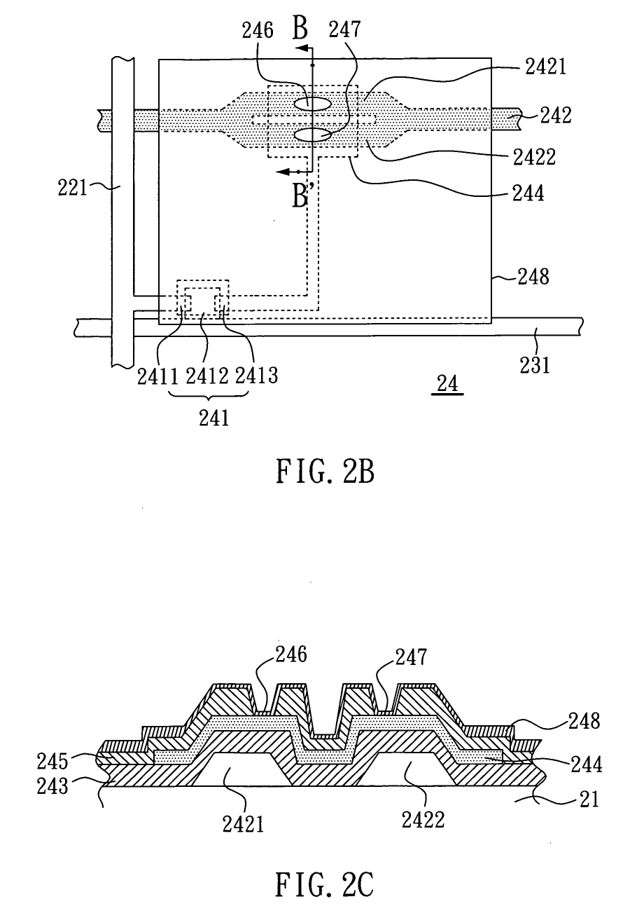

As shown in FIGS. 2A, 2B, and 2C, wherein FIG. 2A is a schematic view of a TFT array substrate of Example 1 of the present invention, FIG. 2B shows the display units of a TFT array substrate of Example 1 of the present invention, and FIG. 2C is a cross-section view along line A-A′ of FIG. 2B.

### Example 1

As shown in FIG. 2A, the TFT array substrate 2 of Example 1 of the present invention comprises: a substrate 21, a plurality of data lines 22 and a plurality of scan lines 23, in which these data lines 22 and scan lines 23 both locate on the substrate 21, which is preferably a glass substrate. Besides, these scan lines 23 and data lines 22 perpendicularly cross each other to form a grid pattern but are not electrically connected with each other, i.e., they divide the substrate into a plurality of display units, i.e. pixel units.

In the present example, shown in FIGS. 2B and 2C, each display unit 24 comprises: a TFT 241, a lower electrode of a storage capacitor 242, a first dielectric layer 243, an upper electrode of the storage capacitor 244, a second dielectric layer 245, three openings 246, 247, and a pixel electrode 248. Wherein the TFT 241 located on the substrate 21 (FIG. 2A) is a bottom-gate type TFT, and has a source 2411, a gate 2412 and a drain 2413. The source 2411 is electrically connected with one of the neighboring data lines 22 (FIG. 2A), and the gate 2412 is electrically connected with one of the neighboring scan lines 23 (FIG. 2A). Moreover, the lower electrode of a storage capacitor 242 is also located on the substrate 21 (FIG. 2A), and further divides into a first portion 2421 and a second portion 2422. The first portion 2421 and the second portion 2422 are separate but electrically connected with each other. The first dielectric layer 243 covers the lower electrode of a storage capacitor 242. The upper electrode of the storage capacitor 244 located on the upper side of the lower electrode of a storage capacitor 242 is formed on the first dielectric layer 243. The second dielectric layer 245 covers the TFT 241 and the upper electrode of the storage capacitor 244. Besides, two openings 246, 247 are formed in the second dielectric layer 245 respectively to expose the partial drain 2413 of the TFT 241, the upper electrode of the storage capacitor 244 located on the upper side of the first portion 2421 of the lower electrode of the storage capacitor 242, and the upper electrode of the storage capacitor 244 located on the upper side of the second portion 2422 of the lower electrode of a storage capacitor 242. Besides, both these two openings 246, 247 are preferably via holes. The pixel electrode 248 formed on the second dielectric layer 245, and the material of the pixel electrode 248 is a transparent conductive material, preferably indium tin oxide (ITO) or indium zinc oxide (IZO). The pixel electrode 248 electrically connects with the drain 2413 of the TFT 241 and the upper electrode of the storage capacitor 244 through these two openings 246, 247.

Accordingly, the display unit 24 comprises a storage capacitor (not shown) inside, because the display unit 24 has a first dielectric layer 243 located between the lower electrode of a storage capacitor 242 and the upper electrode of the storage capacitor 244. In the present embodiment, the lower electrode of a storage capacitor 242 further divides into a first portion 2421 and a second portion 2422 with nearly the same width. Thus this storage capacitor (not shown) may further divide into a first storage capacitor (not shown) and a second storage capacitor (not shown) when the display units 24 operate, and provide actuating current for displaying.

As shown in FIG. 2B, the TFT array substrate of the Example 1 may control each of the display units thereof by a source driver IC (integrated circuit, not shown) and a gate driver IC (not shown), because the source 2411 of the TFT 241 of each display unit 24 is electrically connected with one of the data lines 22 nearby (e.g. data lines 221 of FIG. 2B) in FIG. 2A, and also the gate 2412 of the TFT 241 of each display unit 24 is electrically connected with one of the scan lines 23 nearby (e.g. scan lines 231 of FIG. 2B) in FIG. 2A. As can be seen in FIGS. 2B and 2C, when the display units 24 work, a control signal coming from TFT 241 passes through the two openings 246 and 247 to arrive at pixel electrode 248, thus changing the electric potential of pixel electrode 248 to change the status of the LCD molecule. On the other hand, the current from the first storage capacitor (not shown) or the second storage capacitor (not shown) reaches pixel electrode 248 when the TFT array substrate 2 of the Example 1 is “operating”, and provides operating current for pixel electrode 248 to keep its electric potential, because the pixel electrode 248 also electrically connects with the upper electrode of the storage capacitor 244 through openings 247, 248.

Though in the present embodiment, the TFT array substrate 2 of the Example 1 is a TFT array substrate of the LCD device, it also could be an Active Matrix Organic Light-Emitting Display (AMOLED) TFT array substrate for activating an AMOLED.

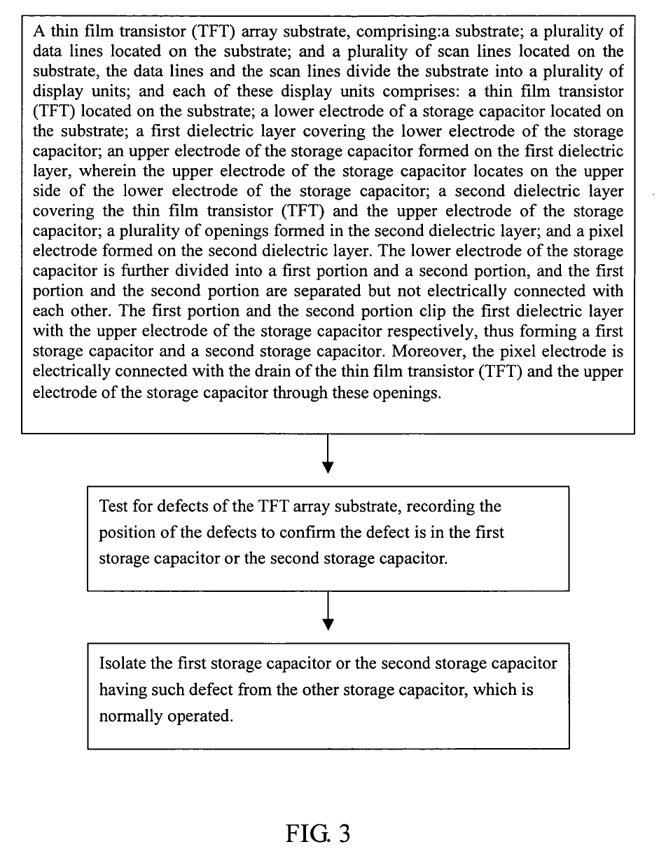

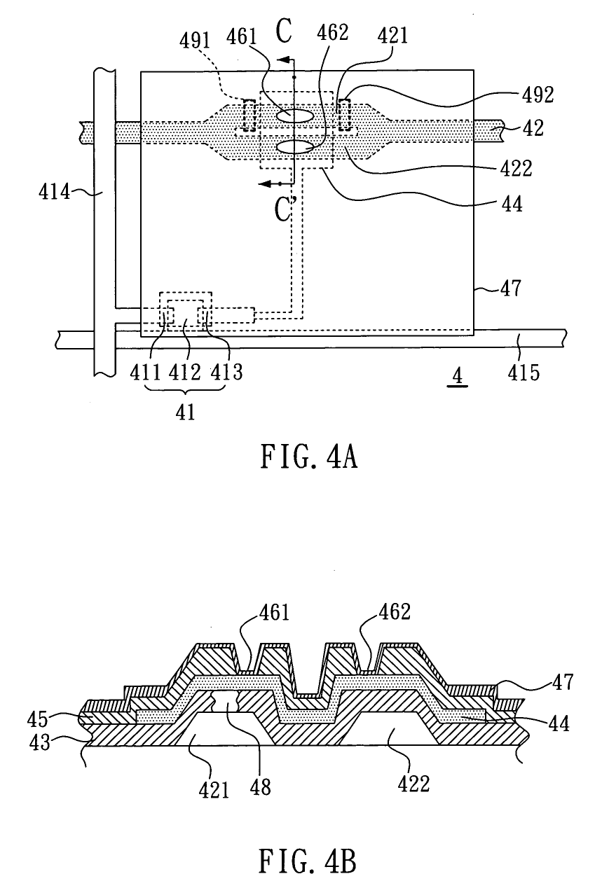

The reason why the leakage current of the storage capacitor of the display unit in the TFT array substrate of the Example 1 is repairable is further described below in accompanying with FIGS. 3, 4A and 4B.

FIG. 3 is a flowchart showing the method of repairing defects of the TFT array substrate of Example 1. As can be seen in FIG. 3, the method thereof comprises:
(A) providing a TFT array substrate, which comprises: a substrate; a plurality of data lines located on the substrate; and a plurality of scan lines located on the substrate, such scan lines and data lines divide the substrate into a plurality of display units, and each of these display units comprises: a thin film transistor (TFT) located on the substrate; a lower electrode of a storage capacitor located on the substrate; a first dielectric layer covering the lower electrode of the storage capacitor; an upper electrode of the storage capacitor formed on the first dielectric layer, wherein the upper electrode of the storage capacitor locates on the upper side of the lower electrode of the storage capacitor; a second dielectric layer covering the TFT and the upper electrode of the storage capacitor; a plurality of openings formed in the second dielectric layer; and a pixel electrode formed on the second dielectric layer. Besides, the lower electrode of the storage capacitor is further divided into a first portion and a second portion, wherein the first portion and the second portion are separated, but they are electrically connected with each other. The first portion and the second portion clip the first dielectric layer with the upper electrode of the storage capacitor respectively, thus forming a first storage capacitor and a second storage capacitor. The pixel electrode is electrically connected with the TFT and the upper electrode of the storage capacitor through the openings;
(B) testing for defects of the TFT array substrate, recording the position of the defects to confirm the defect is in the first storage capacitor or the second storage capacitor; and
(C) isolating the first storage capacitor or the second storage capacitor having such defect from the other storage capacitor, which is normally operated.

The display units of the TFT array substrate provided from the step (A) above are shown in FIG. 4A and FIG. 4B. Accordingly, FIG. 4A shows a display unit of a TFT array substrate of the present invention, wherein the display unit has leakage current. FIG. 4B is a cross-section view along line C-C′ of FIG. 4A.

As can be seen from FIGS. 4A and 4B, the display unit 4 has the same structure with the display units in FIGS. 2B and 2C of Example 1 of the present invention. Also, the display unit 4 comprises: a TFT 41, a lower electrode 42 of a storage capacitor, a first dielectric layer 43, an upper electrode of the storage capacitor 44, a second dielectric layer 45, two openings 461, 462, and a pixel electrode 47. Wherein the TFT 41 located on a substrate (not shown) is a bottom-gate type TFT, and has a source 411, a gate 412 and a drain 413. The source 411 is electrically connected with one of the neighboring data lines 414, and the gate 412 is electrically connected with one of the neighboring scan lines 415. Besides, the lower electrode 42 of a storage capacitor locates on a substrate (not shown), wherein the lower electrode 42 is further divided into a first portion 421 and a second portion 422, and the first portion 421 and the second portion 422 are separated but electrically connected with each other. The first dielectric layer 43 covers the lower electrode 42 of the storage capacitor, and the upper electrode 44 of the storage capacitor is formed on the first dielectric layer 43, wherein the upper electrode 44 of the storage capacitor is located on the upper side of the lower electrode 42 of the storage capacitor. The second dielectric layer 45 covers the TFT 41 and the upper electrode 44 of the storage capacitor. Moreover, two openings 461, 462 are formed in the second dielectric layer 45 respectively to expose the partial drain 413 of the TFT 41, the upper electrode 44 of the storage capacitor locating on the upper side of the first portion 421 of the lower electrode 42 of the storage capacitor, and the upper electrode 44 of the storage capacitor located on the upper side of the second portion 422 of the lower electrode 42 of the storage capacitor. Specifically, both these two openings 461, 462 are preferably via holes. Finally, the pixel electrode 47 is formed on the second dielectric layer 45, and the material of the pixel electrode 47 is preferably indium tin oxide (ITO) or indium zinc oxide (IZO). The pixel electrode 47 electrically connects with the drain 413 of the TFT 41 and the upper electrode 44 of the storage capacitor through these two openings 461, 462.

As mentioned above, the display unit 4 has a storage capacitor (not shown), because the first dielectric layer 43 is located between the lower electrode 42 and the upper electrode 44 of the storage capacitor. In the present example, the lower electrode 42 is divided into a first portion 421 and a second portion 422 having about the same width, thus the storage capacitor is further divided into a first storage capacitor and a second storage capacitor which provide operating current when display unit 4 is required to illuminate.

Moreover, as shown in FIGS. 4A and 4B, when display unit 4 is illuminating, a control signal from the TFT 41 reaches the pixel electrode 47 through the two openings 461, 462, and enhances potential changes to vary the status of the liquid crystal. Also, the pixel electrode 47 electrically connects with the upper electrode 44 of the storage capacitor through the two openings 462, 463, when the TFT array substrate 4 is in its “displaying status”, the current from the above storage capacitor (not shown) reaches the pixel electrode 47 to provide the pixel electrode 47 with enough operating current to keep its potential.

However, with reference to FIG. 4B, in the display unit 4 having defects, the “leakage current” occurs in the defect region 48 of the first storage capacitor (not shown), which is formed by clipping the first dielectric layer 43 with the first portion 421 of the lower electrode 42 and the upper electrode 44 of the storage capacitor, thus the first dielectric layer 43 loses its insulating capacity. As a result, the first storage capacitor (not shown) cannot operate normally (storing current), thus causes TFT 41 to not be able to control display unit 4. Herein, no matter what status (on or off) the display unit 4 is in, the pixel electrode 47 will always be in the same driving potential, i.e. the display unit 4 no longer has two different statuses, thus causing a continuous bright point or a continuous dark point.

Then, in the next process of repairing TFT array substrate of the example 1, i.e. in the step (B), test if there is any defect existing, and then record the position of those defects (leakage current). Referring to FIG. 4B, the defect (leakage current) is located in the first dielectric layer 43 of the defect region 48.

Finally, in the final process of repairing TFT array substrate of the example 1, i.e. in the step (C), isolating process isolates the first storage capacitor having such defect from the other storage capacitor which is operating normally. That is, a laser is used to cut-off the cutting region 491, 492 at the two ends of the first portion 421 of the lower electrode 42, thus isolating the first portion 421 of the lower electrode 42 from the normally operating part of the lower electrode 42 (i.e. the second portion 422 of the lower electrode 42). Consequently, the storage capacitor (not shown) of the display unit 4 having a defect is capable of storing current again, and the pixel electrode 47 is thus recovered. Meanwhile, when a display unit 4 having leakage current is “displaying”, the current from the above second storage capacitor (not shown) is able to reach the pixel electrode 47 to provide pixel electrode 47 with enough operating current to keep its potential, thus making the display unit 4 work normally.

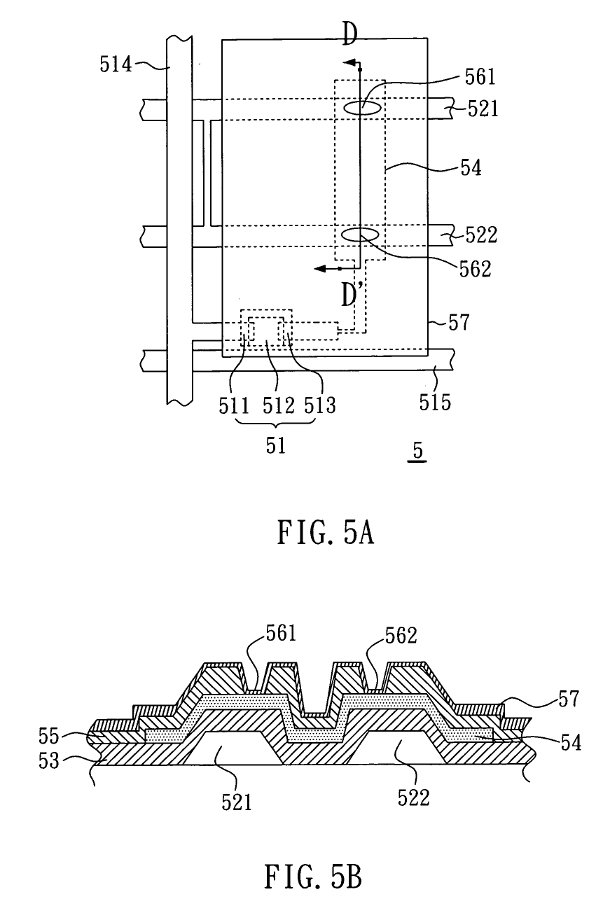

Finally, as shown in FIGS. 5A and 5B, wherein FIG. 5A is the display unit of a TFT array substrate of Example 2 of the present invention, and FIG. 5B is a cross-section view along line D-D′ of FIG. 5A, the display unit 5 of a TFT array substrate of Example 2 of the present invention comprises: a TFT 51, two lower electrodes 521 and 522 of a storage capacitor, a first dielectric layer 53, an upper electrode 54 of the storage capacitor, a second dielectric layer 55, two openings 561 and 562, and a pixel electrode 57. Wherein the TFT 51 located on a substrate (not shown) has a bottom gate structure, and a source 511, a gate 512, and a drain 513. Besides, the source 511 and the data line 514 are electrically connected to each other, and the gate 512 and the scan line 515 are electrically connected to each other. Also, the two lower electrodes 521, 522 of the storage capacitor are located on the substrate and electrically connected to each other, i.e. the two lower electrodes 521, 522 of the storage capacitor are electrically connected to the two lower electrodes of a storage capacitor of the display units (not shown) respectively. Furthermore, these two lower electrodes of a storage capacitor of the display units are electrically connected to a connecting unit (not shown), thus causing those two lower electrodes of a storage capacitor of the display unit electrically connected to each other. On the other hand, the first dielectric layer 53 covers the two electrodes of a storage capacitor 521 and 522, the upper electrode of the storage capacitor 54 is formed on the first dielectric layer 53 and located on the upper side of the lower electrodes 521, 522 of a storage capacitor, and the second dielectric layer 55 covers the TFT 51 and the upper electrode 54 of the storage capacitor. Besides, the two openings 561 and 562 are formed in the second dielectric layer 55 to expose some part of drain 513 of the TFT 51, some part of the upper electrode of the storage capacitor 54 located on the upper side of the lower electrode of a storage capacitor 521, and some part of the upper electrode of the storage capacitor 54 located on the upper side of the lower electrode of a storage capacitor 522. Preferably, these two openings 561 and 562 are via holes. Finally, the pixel electrode 57 is formed on the second dielectric layer 55, the material of the pixel electrode 57 is preferably indium tin oxide (ITO), or indium zinc oxide (IZO), and the pixel electrode 57 is electrically connected with the drain 513 of the TFT 51 and the upper electrode of the storage capacitor 54 through these two openings 561 and 562.

As mentioned above, the display unit 5 has two storage capacitors (not shown), i.e. the first storage capacitor or the second storage capacitor (not shown), because the first dielectric layer 53 is located between the two lower electrodes 521, 522 and the upper electrode 54 of the storage capacitor, thus these two storage capacitors provide operating current for displaying when the display unit 5 operates. Moreover, with reference to FIG. 5A, the TFT array substrate of example 2 of the present invention is able to control each of its display units by a source-driver IC (integrated circuit, not shown) and a gate-driver IC (integrated circuit, not shown), because the source 511 of the TFT 51 of the display unit 5 is electrically connected to a data line 514, and the gate 512 of the TFT 51 is also electrically connected to a scan line 515 described above. Furthermore, referring to FIGS. 5A and 5B, a control signal coming from the TFT 51 passes through the two openings 561 and 562 to reach the pixel electrode 57 when the display unit 5 is illuminating, thus enhancing potential changes of the pixel electrode 57 to vary the status of the liquid crystal thereof. Besides, the current from the first storage capacitor (not shown) or the second storage capacitor (not shown) reaches the pixel electrode 57 when the TFT array substrate 5 of the Example 2 is “operating (on)”, and provides operating current for pixel electrode 57 to keep its potential, because the pixel electrode 57 also electrically connects with the upper electrode 54 of the storage capacitor through openings 562, 563. Further, in these examples, the count of the lower electrodes of a storage capacitor is not limited to the count in FIG. 5A, which can be other appropriate quantities. Also, the widths of the lower electrode of the storage capacitor is not limited, they can be any appropriate widths.

Finally, the display unit 5 of the TFT array substrate of the example 2 of the present invention also can be a display unit (pixel units) of a TFT array substrate of an active matrix organic electro-luminescent display (OELD) device, although the display unit 5 of the present example is a display unit (pixel units) of a TFT array substrate of an LCD device, thus an active matrix organic electro-luminescent display (OELD) device is driven by the display unit 5 to display.

As demonstrated above, the lower electrode of the display unit (pixel unit) of the present TFT array substrate is further divided into a first portion and a second portion, or the display unit has more than two lower electrodes of a storage capacitor electrically connected with each other. Therefore, when the “leakage current” occurs in the storage capacitor in the display units of the TFT array substrate of the present invention, it is possible to use a laser to cut-off the two ends of some parts of the storage capacitor (the first storage capacitor or the second storage capacitor) having “leakage current”, that is, the repairing method of the present invention isolates the normal storage capacitor from the storage capacitor having “leakage current”. Consequently, after repair, the other parts of the storage capacitor having no “leakage current” still store the current inside normally, thus the display units having “leakage current” are recovered to be able to display again and to be able to be controlled by the TFT thereof.

Besides, comparing to the display units (pixel units) of the traditional TFT array substrate, there are only changes on the shape of the lower electrode of a storage capacitor of the TFT array substrate display units (pixel units) of the present invention, and the shape change (e.g. the lower electrode of a storage capacitor further divided into a first portion or a second portion) can be easily obtained from adjusting the pattern of the mask. Thus, the TFT array substrate of the present invention can be fabricated using the traditional method of fabricating the TFT array substrate without increasing manufacturing cost. Consequently, the “leakage current” occurring in display units (pixel units) of the TFT array substrate of the present invention is easily repaired, so as to reduce the count of defects (i.e. bright point or black point) causing by the “leakage current”, and further to improve the displaying quality of the TFT array substrate of the present invention.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A thin film transistor (TFT) array substrate, comprising:
a substrate;
a plurality of data lines located on the substrate; and
a plurality of scan lines located on the substrate, substantially perpendicularly crossing the data lines in a grid pattern, wherein the data lines and the scan lines divide the substrate into a plurality of display units, and each of these display units comprises:
a thin film transistor (TFT) located on the substrate, having a source, a gate, and a drain, at which the source is electrically connected with one of the neighboring data lines, and the gate is electrically connected with one of the neighboring scan lines;
a lower electrode of a storage capacitor located on the substrate, wherein the lower electrode is further divided into a first portion and a second portion, and the first portion and the second portion are separated from each other but electrically connected with each other;
a first dielectric layer covering the lower electrode of the storage capacitor;
an upper electrode of the storage capacitor formed on the first dielectric layer, wherein the upper electrode of the storage capacitor is located on the upper side of the lower electrode of the storage capacitor;
a second dielectric layer covering the thin film transistor (TFT) and the upper electrode of the storage capacitor;
a plurality of openings formed in the second dielectric layer, so as to expose a partial drain of the thin film transistor (TFT), the upper electrode of the storage capacitor located on the upper side of the first portion of the lower electrode of the storage capacitor, and the upper electrode of the storage capacitor located on the upper side of the second portion of the lower electrode of the storage capacitor; and
a pixel electrode formed on the second dielectric layer, wherein the pixel electrode is electrically connected with the drain of the thin film transistor (TFT) and the upper electrode of the storage capacitor through the openings.

2. The thin film transistor (TFT) array substrate as claimed in claim 1, further comprising a glass substrate.

3. The thin film transistor (TFT) array substrate as claimed in claim 1, wherein the display units are pixel units of the TFT array substrate.

4. The thin film transistor (TFT) array substrate as claimed in claim 1, wherein the material of the pixel electrode comprises indium tin oxide, indium zinc oxide, or transparent conductive materials.

5. The thin film transistor (TFT) array substrate as claimed in claim 1, wherein the first portion of the lower electrode of the storage capacitor has a width the same size as the width of the second portion of the lower electrode of the storage capacitor.

6. The thin film transistor (TFT) array substrate as claimed in claim 1, wherein the thin film transistor (TFT) comprises a bottom-gate type thin film transistor (TFT).

7. A thin film transistor (TFT) array substrate, comprising:
a substrate;
a plurality of data lines located on the substrate; and
a plurality of scan lines located on the substrate, substantially perpendicularly crossing the data lines in a grid pattern, wherein the data lines and the scan lines divide the substrate into a plurality of display units, and each of these display units comprises:
a thin film transistor (TFT), located on the substrate, having a source, a gate, and a drain, at which the source is electrically connected with one of the neighboring data lines, and the gate is electrically connected with one of the neighboring scan lines;
a plurality of lower electrodes of a storage capacitor located on the substrate, wherein the lower electrodes of the storage capacitor are separated from each other but electrically connected with each other;
a first dielectric layer covering the lower electrode of the storage capacitor;
a plurality of upper electrodes of the storage capacitor formed on the first dielectric layer, wherein the upper electrode of the storage capacitor is located on the upper side of the lower electrode of the storage capacitor;
a second dielectric layer covering the thin film transistor and the upper electrode of a storage capacitor;
a plurality of openings formed in the second dielectric layer, so as to expose a partial drain of the thin film transistor (TFT) and the upper electrode of the storage capacitor located on the upper side of the lower electrode of the storage capacitor; and
a pixel electrode formed on the second dielectric layer, wherein the pixel electrode is electrically connected with the drain of the thin film transistor (TFT) and the upper electrode of the storage capacitor through these openings.

8. The thin film transistor (TFT) array substrate as claimed in claim 7, further comprising a glass substrate.

9. The thin film transistor (TFT) array substrate as claimed in claim 7, wherein the display units are pixel units of the thin film transistor (TFT) array substrate.

10. The thin film transistor (TFT) array substrate as claimed in claim 7, wherein the material of the pixel electrode includes indium tin oxide, indium zinc oxide or transparent conductive materials.

11. The thin film transistor (TFT) array substrate as claimed in claim 7, wherein each of the lower electrodes of the storage capacitor has the same width.

12. The thin film transistor (TFT) array substrate as claimed in claim 7, wherein each of the upper electrodes of the storage capacitor has the same width.

13. The thin film transistor (TFT) array substrate as claimed in claim 7, wherein the thin film transistor (TFT) comprises a bottom-gate type thin film transistor (TFT).
